(19) United States
(12) Patent Application Publication
(10) Pub. No.: US 2024/0395590 A1
(43) Pub. Date: Nov. 28, 2024

(54) DEVICE AND METHOD FOR TRANSFERRING SEMICONDUCTOR COMPONENT

(71) Applicant: JI HUA LABORATORY, Foshan (CN)

(72) Inventors: Yanliang QIN, Foshan (CN); Shuaibei YU, Foshan (CN); Yi LI, Foshan (CN); Zhenting LIANG, Foshan (CN); Peipei CHEN, Foshan (CN); Cheng XU, Foshan (CN); Detian TIAN, Foshan (CN); Yu WANG, Foshan (CN); Ning AN, Foshan (CN)

(73) Assignee: JI HUA LABORATORY, Foshan (CN)

(21) Appl. No.: 18/792,285

(22) Filed: Aug. 1, 2024

Related U.S. Application Data
(63) Continuation of application No. PCT/CN2024/082158, filed on Mar. 18, 2024.

(30) Foreign Application Priority Data
Apr. 28, 2023 (CN) 202310480227.X

(51) Int. Cl. H01L 21/68; H01L 21/683; H01L 25/075; H01L 33/00

(52) U.S. Cl. CPC H01L 21/681; H01L 21/6835; H01L 25/0753; H01L 33/0093; H01L 2221/68368

(57) ABSTRACT

Disclosed are a device and a method for transferring the semiconductor component, which aims to accurately measure the movement accuracy of a transfer stamp when transferring semiconductor components using a transfer stamp, thereby improving the alignment accuracy between the transfer stamp and the semiconductor component, ensuring the yield rate of the prepared products, and solving the problem in the related art that after the transfer stamp is aligned with a temporary carrier or a drive circuit backplane, the semiconductor components cannot be guaranteed by only relying on the large stroke up and down movement of the guide rail. The precise picking up of LED chips or accurate placement of them at the predetermined position on the driver circuit backplane results in a decrease in the transfer yield, affecting the technical issues of subsequent related processes.

### CROSS-REFERENCE TO RELATED APPLICATIONS

This application is a continuation application of International Application No. PCT/CN2024/082158, filed on Mar. 18, 2024, which claims priority to Chinese Patent Application No. 202310480227.X, filed on Apr. 28, 2023. The disclosures of the above-mentioned applications are incorporated herein by reference in their entireties.

### TECHNICAL FIELD

The present application relates to the technical field of semiconductor processing, and in particular to a device and a method for transferring a semiconductor component.

### BACKGROUND

Compared with other existing display technologies, such as liquid crystal display (LCD) and organic light-emitting diode (OLED), Micro LED display technology has the advantages of high contrast, high brightness, low power consumption, long life, ultra-thin flexible display, etc., and is regarded as a disruptive and revolutionary next-generation display technology. At present, the manufacturing technology of Micro LED display is to use mass transfer technology to transfer the prepared Micro LED chip to the drive circuit backplane. Specifically, the Micro LED chip manufacturer first manufactures or places the required Micro LED chip on a temporary carrier, and the customer then transfers the Micro LED chip placed on the temporary carrier to the drive circuit of different products according to different needs. However, the size of Micro LED is very small, from tens of microns to several microns. In the process of transferring the Micro LED chip from the temporary carrier to the drive circuit backplane, extremely high transfer accuracy is required, generally about 5% of the size of Micro LED. When the transfer stamp picks up the Micro LED chip on the temporary carrier or releases the Micro LED chip to the drive circuit backplane, it is necessary to first align the transfer stamp with the Micro LED chip on the temporary carrier or the drive circuit backplane, and the alignment action is completed by the alignment unit. During alignment, the alignment unit is located between the transfer stamp and the temporary carrier or the drive circuit backplane. After the alignment is completed, the alignment unit moves horizontally. Limited by the size of the alignment unit, after the transfer stamp and the target are aligned, a large stroke (such as more than 200 mm) downward movement is required to complete the high-precision pickup or release of the Micro LED chip. In addition, after the transfer stamp is aligned with the temporary carrier or the drive circuit backplane, relying solely on the large stroke up and down movement of the guide rail cannot guarantee the accurate pickup of the Micro LED chip or the accurate placement of the Micro LED chip in the predetermined position on the drive circuit backplane, resulting in a decrease in the transfer yield and affecting subsequent related processes.

### SUMMARY

The main objective of the present application is to provide a device and a method for transferring a semiconductor component, aiming to solve the technical problem in the related art that after the transfer stamp is aligned with the temporary carrier or the drive circuit backplane, it can't be ensured that the Micro LED chip is accurately picked up or placed in the predetermined position of the driver circuit backplane, resulting in a decrease in the transfer yield and affecting subsequent related processes.

In order to achieve the above objective, in a first aspect, the present application provides a device for transferring the semiconductor component, including: a base frame including a transport platform and a support frame installed at the transport platform, a transfer mechanism including a lifting drive member, a transfer stamp and a sensing component, and a material transport mechanism installed at the transport platform and penetrating the support frame.

In an embodiment, the lifting drive member and the sensing component are installed at intervals at the support frame, the transfer stamp is installed at the lifting drive and is located above the transport platform, the lifting drive is configured to drive the transfer stamp to rise and fall along a Z direction between a first position and a second position, the sensing component is provided close to a lifting path of the transfer stamp, and the sensing component is configured to sense first spatial coordinates of the transfer stamp at the first position and second spatial coordinates of the transfer stamp at the second position.

In an embodiment, the material transport mechanism is provided below the sensing component, the material transport mechanism is provided with a first placement area and a second placement area configured to place the semiconductor component, and the material transport mechanism is configured to move along an X direction to correspond the first placement area or the second placement area with the transfer stamp.

In an embodiment, in response to that the first placement area correspond to the transfer stamp, the transfer stamp is configured to adsorb the semiconductor component placed in the first placement area; and in response to that the second placement area correspond to the transfer stamp, the transfer stamp is configured to place the adsorbed semiconductor component in the second placement area.

In an embodiment, a mounting plate is provided at the support frame, the mounting plate includes a first vertical plate provided along the X direction and a second vertical plate provided along a Y direction, one side of the first vertical plate is connected to one side of the second vertical plate, the first vertical plate and the second vertical plate are enclosed to form a lifting space, the transfer stamp is located in the lifting space, the lifting drive member is installed at a side of the first vertical plate facing the lifting space, a side of the second vertical plate facing the lifting space is provided with a first guide rail extending along the Z direction, the transfer stamp is provided with a first slider slidably matched with the first guide rail, and the sensing component is installed at a side wall of the lifting space.

In an embodiment, the sensing component includes a first sensing component installed at the first vertical plate and a second sensing component installed at the second vertical plate, a first sensing area extending along the Z direction is formed on a side of the transfer stamp corresponding to the first vertical plate, and a second sensing area extending along the Z direction is formed on a side of the transfer stamp corresponding to the second vertical plate; the first sensing component is configured to sense the first spatial coordinates and the second spatial coordinates of the first sensing area, and the second sensing component is configured to sense the first spatial coordinates and the second spatial coordinates of the second sensing area.

In an embodiment, the first sensing region is formed with a first sensing surface extending along the Z direction, the second sensing region is formed with a second sensing surface extending along the Z direction and a third sensing surface extending along the Z direction and spaced apart from the second sensing surface.

In an embodiment, the first sensing component includes two first sensors provided at intervals along the Z direction, and the two first sensors correspond to the first sensing surface, the second sensing component includes a second sensor and two third sensors provided at intervals along the Z direction, the second sensor is provided opposite to the second sensing surface, the two third sensors are opposite to the third sensing surface, the second sensor and the two third sensors are provided at intervals along the Y direction, and the second sensor, the two first sensors and the two third sensors are all configured to sense the first spatial coordinates and the second spatial coordinates.

In an embodiment, the first vertical plate is further provided with a second guide rail extending along the Z direction, the transfer stamp is further provided with a second slider slidably matched with the second guide rail, and the second guide rail is provided at intervals from the lifting drive member.

In an embodiment, the support frame is further provided with a first horizontal drive member, the mounting plate is connected to the first horizontal drive member, and the first horizontal drive member is configured to drive the mounting plate to move along the Y direction to drive the transfer mechanism to move along the Y direction.

In an embodiment, an alignment space can be formed between the material transport mechanism and the transfer stamp, a first alignment point is provided at a bottom surface of the transfer stamp, and a second alignment point is provided at both the first placement area and the second placement area.

In an embodiment, an alignment mechanism is installed at the support frame, the alignment mechanism includes a second horizontal drive member and an alignment component, the first horizontal drive member and the second horizontal drive member are provided at an interval, and the second horizontal drive member is installed at the support frame, the alignment component is connected to the second horizontal drive member, the second horizontal drive member is configured to drive the alignment component to enter the alignment space along the Y direction, and sense the first alignment point and the second alignment point.

In an embodiment, the alignment component includes a mounting seat, a first collector and a second collector, the mounting seat is connected to the output end of the second horizontal drive member, the first collector and the second collector are coaxially mounted on the mounting seat along the Z direction, the first collector corresponds to the transfer stamp and is used to sense the first alignment point, and the second collector corresponds to the first placement area or the second placement area and is configured to sense the second alignment point.

Based on a same technical concept, in a second aspect, the present application provides a method for transferring a semiconductor component, applied to the device for transferring described in the first aspect.

In an embodiment, the method includes: obtaining the first spatial coordinates of the transfer stamp at the first position the first placement area is directly below the transfer stamp;
obtaining the second spatial coordinates of the transfer stamp at the second position;
calculating a posture error of the transfer stamp after movement according to the first spatial coordinates and the second spatial coordinates;
correcting the transfer stamp according to the posture error;
adsorbing the semiconductor component placed on the first placement area; and
in response that the second placement area being opposite to the transfer stamp, placing the semiconductor component in the second placement area.

In an embodiment, the calculating the posture error of the transfer stamp after movement according to the first spatial coordinates and the second spatial coordinates includes:
calculating first error data of the transfer stamp using formula 1 according to the first spatial coordinates and the second spatial coordinates; the first error data ΔX includes the displacement error of the transfer stamp along the X direction and the displacement error ΔY along the Y direction, and the formula 1 is:

$$\{ \begin{matrix}Δ X = \frac{{X}_{Ai} + {X}_{Ci}}{2} \\ Δ Y = \frac{{Y}_{Di} + {Y}_{Ei}}{2}\end{matrix} ,$$

X_{Ai} is an X axis coordinate change of a third sensor located above, X_{Ci} is an X axis coordinate change of a third sensor located below, Y_{Di} is a Y axis coordinate change of a first sensor located above, and Y_{Ei} is a Y axis coordinate change of a first sensor located below;
calculating a rotation angle error Rₓ of the transfer stamp around the X axis, a rotation angle error R_{y} of the transfer stamp around the Y axis, and a rotation angle error R_{z} of the transfer stamp around the Z axis using formula 2, formula 2 is:

$$\{ \begin{matrix}{R}_{x} = a tan ( \frac{{Y}_{Di} - {Y}_{Ei}}{{L}_{3}} ) \\ {R}_{y} = a tan ( \frac{{X}_{Ai} - {X}_{Ci}}{{L}_{2}} ) \\ {R}_{z} = a tan ( \frac{{X}_{Ai} - {X}_{Bi}}{{L}_{1}} )\end{matrix} ,$$

X_{Bi} is an X axis coordinate change of the second sensor, L₁ is a horizontal distance between the second sensor and the third sensor located above, L₂ is a vertical height of the two third sensors along the Z axis, and L₃ is a vertical height of the two third sensors along the Z axis;
calculating a displacement result of the transfer stamp using formula 3 according to the movement stroke Hz of the transfer stamp, ΔX, ΔY, Rₓ and R_{y} to obtain the posture error of the transfer stamp after movement; the displacement result includes the displacement value X₁ in the X direction and the displacement value Y₁ in the Y direction, and formula 3 is:

$$\{ \begin{matrix}{X}_{1} = Δ X - ( {H}_{z} + \frac{{L}_{3}}{2} + {δ}_{x} ) tan {R}_{y} \\ {Y}_{1} = Δ Y - ( {H}_{z} + \frac{{L}_{2}}{2} + {δ}_{y} ) tan {R}_{x}\end{matrix} ;$$

δₓ is a vertical distance between the bottom surface of the transfer stamp and the third sensor located below, and δ_{y} is a vertical distance between the bottom surface of the transfer stamp and the first sensor located below.

In the technical solution of the present application, a base frame is provided, a support frame is installed at the transport platform of the base frame. The lifting drive member and the sensing component in the transfer mechanism are installed at the support frame at intervals. The transfer stamp is installed at the lifting drive member and is located above the transport platform. The lifting drive member can drive the transfer stamp to rise and fall along the Z direction between the first position and the second position. The sensing component is provided close to the lifting path of the transfer stamp. The sensing component is used to sense the first spatial coordinate of the transfer stamp at the first position and the second spatial coordinate of the transfer stamp at the second position. At the same time, a material transport mechanism is installed at the transport platform and penetrated through the support frame. The material transport mechanism is provided below the sensing component. The material transport mechanism is provided with a first placement area and a second placement area for placing the semiconductor component. The material transport mechanism can move along the X direction so that the first placement area or the second placement area corresponds to the transfer stamp. Then, when the first placement area corresponds to the transfer stamp, the transfer stamp can adsorb the semiconductor components placed in the first placement area. When the second placement area corresponds to the transfer stamp, the transfer stamp can place the adsorbed semiconductor components in the second placement area, achieving the purpose of accurately measuring the movement accuracy of the transfer stamp when using the transfer stamp to transfer the semiconductor component, which can improve the alignment accuracy between the transfer stamp and the semiconductor components, ensure the yield rate of the prepared products, and solve the problem in the related art that after the transfer stamp is aligned with the temporary carrier or the drive circuit backplane, it can't be ensured that the Micro LED chip is accurately picked up or placed in the predetermined position of the driver circuit backplane relying solely on the large stroke up and down movement of the guide rail, resulting in a decrease in the transfer yield and affecting subsequent related processes.

### BRIEF DESCRIPTION OF THE DRAWINGS

In order to more clearly illustrate the technical solutions in the embodiments of the present application or in the related art, drawings used in the embodiments or in the related art will be briefly described below. Obviously, the drawings in the following description are only some embodiments of the present application. It will be apparent to those skilled in the art that other figures can be obtained according to the structures shown in the drawings without creative work.

FIG. 1 is a schematic diagram of a three-dimensional structure of a device for transferring a semiconductor component according to an embodiment of the present application.

FIG. 2 is a schematic structural diagram of a transfer mechanism shown in FIG. 1.

FIG. 3 is a schematic diagram of a planar structure of the transfer mechanism shown in FIG. 2.

FIG. 4 is a schematic diagram of an installation structure of an installation plate and a sensing component shown in FIG. 1.

FIG. 5 is a schematic diagram of a working state of an alignment mechanism according to the present application.

FIG. 6 is a schematic structural diagram of the alignment mechanism shown in FIG. 5 when retracted.

FIG. 7 is a schematic structural diagram of a transfer stamp moving to a first placement area or a second placement area.

FIG. 8 is a flowchart of a method for transferring the semiconductor component according to the present application.

The realization of the purpose, functional features and advantages of the present application will be further described with reference to the embodiments and the accompanying drawings.

### DETAILED DESCRIPTION OF THE EMBODIMENTS

In order to enable those skilled in the art to better understand the present application, the following will be combined with the drawings in the embodiments of the present application to clearly and completely describe the technical solutions in the embodiments of the present application. Obviously, the described embodiments are only embodiments of a part of the present application, not all embodiments. Based on the embodiments in the present application, all other embodiments obtained by ordinary skilled in the art without creative work should fall within the scope of protection of this application.

It should be noted that all of the directional instructions in the embodiments of the present disclosure (such as, up, down, left, right, front, rear . . . ) are only used to explain the relative position relationship and movement of each component under a specific attitude (as shown in the drawings), if the specific attitude changes, the directional instructions will change correspondingly.

In the present application, unless otherwise clearly stated and limited, the terms “connection”, “fixing”, etc. should be understood in a broad sense. For example, “fixing” can be a fixed connection, a detachable connection, or an integral body; it can be a mechanical connection or an electrical connection; it can be a direct connection or an indirect connection through an intermediate medium; it can be an internal connection between two elements or an interactive relationship between two elements, unless otherwise clearly limited. For those of ordinary skill in the art, the specific meanings of the above terms in the present application can be understood according to specific circumstances.

Besides, the descriptions in the present disclosure that refer to “first,” “second,” etc. are only for descriptive purposes and are not to be interpreted as indicating or implying relative importance or to implicitly indicate the number of technical features indicated. Thus, a feature defined as “first” or “second” may explicitly or implicitly include at least one of the features. Additionally, the term “and/or” used throughout the specification encompasses three scenarios. Taking A and/or B as an example, it includes the technical solution of A, the technical solution of B, and the technical solution where both A and B are satisfied simultaneously. Furthermore, the technical solutions of the various embodiments can be combined with each other, but such combinations must be based on the ability of those skilled in the art to implement them. If the combination of technical solutions results in contradictions or is unfeasible, it should be considered that such a combination does not exist and is not within the scope of protection claimed by the present application.

The inventive concept of the present application is further explained below in conjunction with some embodiments.

The present application provides a device and a method for transferring the semiconductor component.

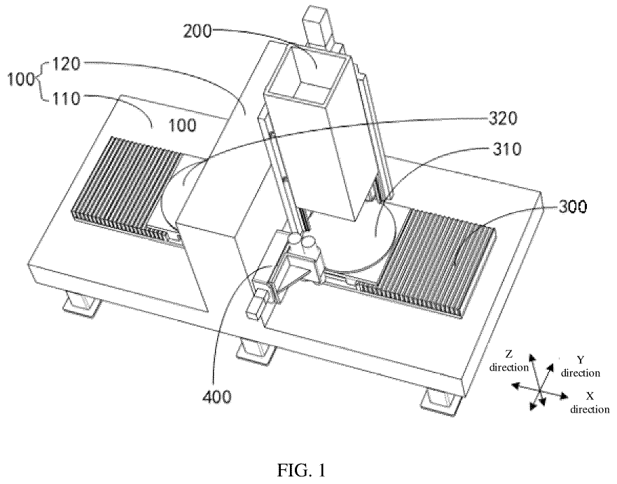

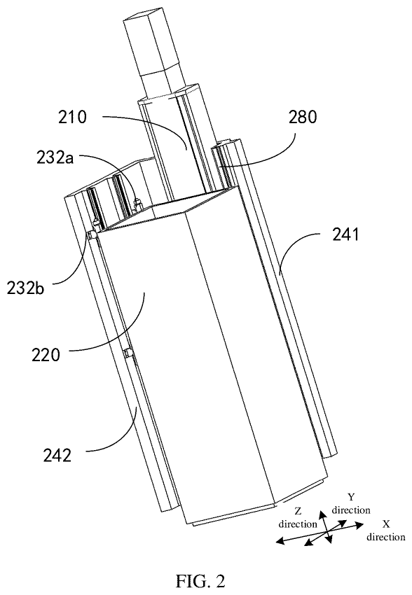

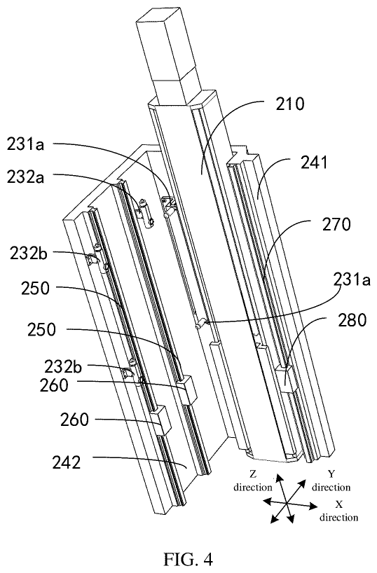

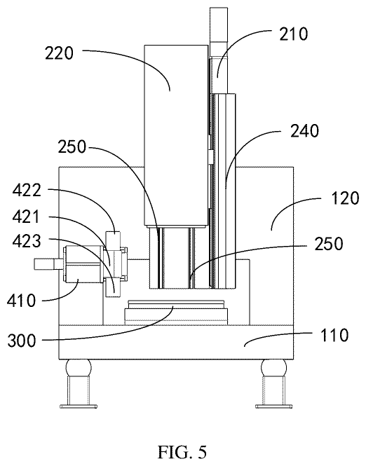

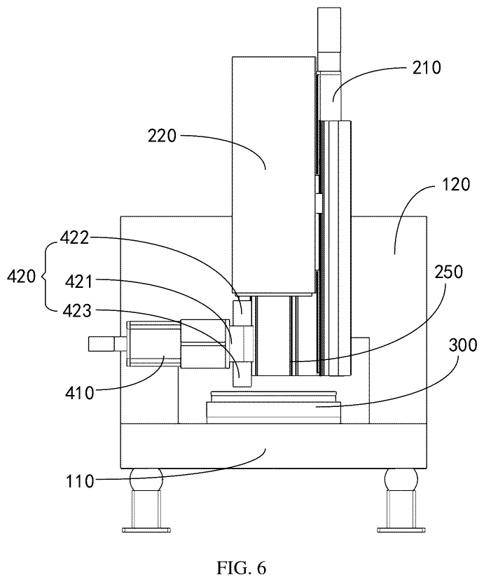

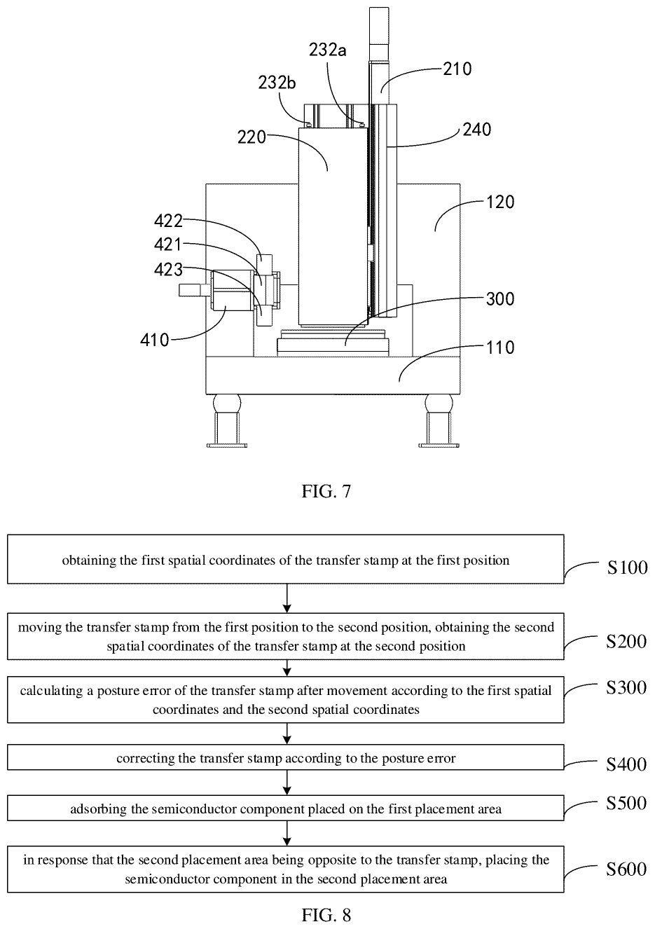

In an embodiment, as shown in FIG. 1 to FIG. 7, the device and the method for transferring the semiconductor component of the present application are provided.

In an embodiment, as shown in FIG. 1 to FIG. 7. The device for transferring the semiconductor component includes: abase 100, a transfer mechanism 200, and a material transport mechanism 300.

The base frame 100 includes a transport platform 110 and a support frame 120 installed at the transport platform 110.

The transfer mechanism 200 includes a lifting drive member 210, a transfer stamp 220 and a sensing component 230. The lifting drive member 210 and the sensing component 230 are installed at intervals at the support frame 120. The transfer stamp 220 is installed at the lifting drive member 210 and is located above the transport platform 110. The lifting drive member 210 can drive the transfer stamp 220 to rise and fall along the Z direction between a first position and a second position. The sensing component 230 is provided close to the lifting path of the transfer stamp 220. The sensing component 230 is configured to sense the first spatial coordinates of the transfer stamp 220 at the first position and the second spatial coordinates of the transfer stamp at the second position.

The material transport mechanism 300 is installed at the transport platform 110 and penetrates the support frame 120. The material transport mechanism 300 is provided below the sensing component 230. The material transport mechanism 300 is provided with a first placement area 310 and a second placement area 320 for placing the semiconductor components. The material transport mechanism 300 can move along the X direction to correspond the first placement area 310 or the second placement area 320 with the transfer stamp 220.

In response to that the first placement area 310 corresponds to the transfer stamp 220, the transfer stamp 220 can adsorb the semiconductor components placed in the first placement area 310. In response to that the second placement area 320 corresponds to the transfer stamp 220, the transfer stamp 220 can place the adsorbed semiconductor components in the second placement area 320.

In an embodiment, the sensing component 230 is configured to obtain the first spatial coordinates information of the transfer stamp 220 at the first position and the second spatial coordinates information of the transfer stamp 220 at the second position when it is directly lifted and lowered along the Z direction. The first spatial coordinate information and the second spatial coordinate information can be configured to calculate whether the transfer stamp 220 is offset in the X direction and the Y direction and the specific offset value. At the same time, it is determined whether rotation occurs around the X axis, the Y axis and the Z axis respectively, and the corresponding rotation value. Therefore, the present application can accurately determine whether the transfer stamp 220 is aligned with the semiconductor components placed in the first placement area 310 or the second placement area 320 during implementation.

It should be particularly and clearly stated that in an embodiment, the sensing component 230 may be, but is not limited to, a charge coupled device (CCD) camera or an infrared distance sensor or a displacement sensor, etc., which are existing devices or apparatuses that can be used to obtain spatial coordinate information. No further details will be given here.

In an embodiment, a base frame 100 is provided. A support frame 120 is installed at the transport platform 110 of the base frame 100. The lifting drive member 210 and the sensing component 230 in the transfer mechanism 200 are installed at intervals on the support frame 120. The transfer stamp 220 is installed at the lifting drive member 210 and is located above the transport platform 110. The lifting drive member 210 can drive the transfer stamp 220 to rise and fall along the Z direction between the first position and the second position. The sensing component 230 is provided close to the lifting path of the transfer stamp 220. The sensing component 230 is used to sense the first spatial coordinates of the transfer stamp 220 at the first position and the second spatial coordinates at the second position. At the same time, the material transport mechanism 300 is installed at the transport platform 110 and penetrated in the support frame 120. The material transport mechanism 300 is provided below the sensing component 230. The material transport mechanism 300 is provided with a first placement area 310 and a second placement area 320 configured to place the semiconductor components. The material transport mechanism 300 can move along the X direction so that the first placement area 310 or the second placement area 320 corresponds to the transfer stamp 220. Then, when the first placement area 310 corresponds to the transfer stamp 220, the transfer stamp 220 can adsorb the semiconductor components placed in the first placement area 310. When the second placement area 320 corresponds to the transfer stamp 220, the transfer stamp 220 can place the adsorbed semiconductor components in the second placement area 320. The purpose of accurately measuring the movement accuracy of the transfer stamp 220 when using the transfer stamp 220 to transfer semiconductor components, which can improve the alignment accuracy between the transfer stamp 220 and the semiconductor components, ensure the yield rate of the prepared products, and solve the problem in the related art that after the transfer stamp 220 is aligned with the temporary carrier or the drive circuit backplane, it can't be ensured that the Micro LED chip is accurately picked up or placed in the predetermined position of the driver circuit backplane relying solely on the large stroke up and down movement of the guide rail, resulting in a decrease in the transfer yield and affecting subsequent related processes.

In an embodiment, a mounting plate 240 is provided at the support frame 120. The mounting plate 240 includes a first vertical plate 241 provided along the X direction and a second vertical plate 242 provided along the Y direction. One side of the first vertical plate 241 is connected to one side of the second vertical plate 242. The first vertical plate 241 and the second vertical plate 242 are enclosed to form a lifting space. The transfer stamp 220 is located in the lifting space. The lifting drive member 210 is installed at the side of the first vertical plate 241 facing the lifting space. A first guide rail 250 extending along the Z direction is provided at the side of the second vertical plate 242 facing the lifting space. A first slider 260 slidably matched with the first guide rail 250 is provided at the transfer stamp 220. The sensing component 230 is installed at the side wall of the lifting space.

In an embodiment, the mounting plate 240 is provided at the support frame 120. The mounting plate 240 is provided as a first vertical plate 241 provided along the X direction and a second vertical plate 242 provided along the Y direction. Then, the first vertical plate 241 and the second vertical plate 242 are enclosed to form a lifting space. The transfer stamp 220 is located in the lifting space. The side of the second vertical plate 242 away from the lifting space is connected to the support frame 120. At the same time, the lifting drive member 210 is installed at the first vertical plate 241, and a first guide rail 250 extending along the Z direction is provided at the second vertical plate 242. The transfer stamp 220 is installed at the output end of the lifting drive member 210, and the transfer stamp 220 can move up and down along the first guide rail 250, which enables the present application to ensure that when the transfer stamp 220 moves up and down along the Z direction during specific implementation, larger loads can be bear, and no significant rotation or deviation occurs.

It should be particularly and clearly stated that in an embodiment, the lifting drive member 210 can be a device or apparatus in the related art that can drive the transfer stamp 220 to move linearly along the Z direction, which is only applied in the embodiment. Therefore, its specific structure and working principle will not be described here. However, it can be illustrated that the lifting drive member 210 illustrated in the embodiment can be, but not limited to, an air compressor with a cylinder, a servo motor with an electric push rod, a hydraulic pump with a hydraulic cylinder, a screw nut servo motor structure, etc.

In an embodiment, the sensing component 230 includes a first sensing component 231 installed at the first vertical plate 241 and a second sensing component 232 installed at the second vertical plate 242. A first sensing area extending along the Z direction is formed on a side of the transfer stamp 220 corresponding to the first vertical plate 241, and a second sensing area extending along the Z direction is formed on one side of the transfer stamp 220 corresponding to the second vertical plate 242. The first sensing component 231 is configured to sense the first spatial coordinates and the second spatial coordinates of the first sensing area. The second sensing component 232 is configured to sense the first spatial coordinates and the second spatial coordinates of the second sensing area.

In an embodiment, the first sensing component 231 is installed at the first vertical plate 241. The second sensing component 232 is installed at the second vertical plate 242. A first sensing area extending along the Z direction is formed on the side of the transfer stamp 220 corresponding to the first vertical plate 241. A second sensing area extending along the Z direction is formed on the side corresponding to the second vertical plate 242. Then the first sensing component 231 is used to sense and measure the first spatial coordinates and the second spatial coordinates of the first sensing area. And the second sensing component 232 is used to sense the first spatial coordinates and the second spatial coordinates of the second sensing area. When the present application is implemented, the first sensing component 231 can be used to sense and measure the spatial coordinate information of the transfer stamp 220 in the X direction and the second sensing component 232 can be used to sense and measure the spatial coordinate information of the transfer stamp 220 in the Y direction. Then, when the present application is implemented, the offset value of the transfer stamp 220 during the lifting process can be sensed and measured.

In an embodiment, the first sensing region is formed with a first sensing surface 233 extending along the Z direction. The second sensing region is formed with a second sensing surface 234 extending along the Z direction and a third sensing surface 235 extending along the Z direction and spaced apart from the second sensing surface 234.

The first sensing component 231 includes two first sensors 231a provided at intervals along the Z direction. The two first sensors 231a both correspond to the first sensing surface 233. The second sensing component 232 includes a second sensor 232a and two third sensors 232b provided at intervals along the Z direction. The second sensor 232a is provided opposite to the second sensing surface 234. The two third sensors 232b both correspond to the third sensing surface 235. The second sensor 232a and the two third sensors 232b are provided at intervals along the Y direction. The second sensor 232a, the two first sensors 231a and the two third sensors 232b are all configured to sense the first spatial coordinates and the second spatial coordinates.

The first sensing region is formed with a first sensing surface 233 extending along the Z direction. The second sensing region is formed with a second sensing surface 234 extending along the Z direction and a third sensing surface 235 extending along the Z direction and spaced apart from the second sensing surface 234.

The first sensing component 231 includes two first sensors 231a provided at intervals along the Z direction. The two first sensors 231a both correspond to the first sensing surface 233. When the transfer stamp 220 moves along the first sensing surface 233, the two first sensors 231a are used to measure the first spatial coordinates of the transfer stamp 220 at the first position and the second spatial coordinates of the transfer stamp 220 at the second position.

The second sensing component 232 includes a second sensor 232a and two third sensors 232b provided at intervals along the Z direction. The second sensor 232a is provided opposite to the second sensing surface 234. The two third sensors 232b are both opposite to the third sensing surface 235. The second sensor 232a and the two third sensors 232b are provided at intervals along the Y direction.

When the transfer stamp 220 moves along the second sensing surface 234 and the third sensing surface 235, the second sensor 232a and the third sensor 232b located above are used to measure the first spatial coordinates of the transfer stamp 220 at the first position and the second spatial coordinates of the transfer stamp 220 at the second position.

When the transfer stamp 220 moves along the second sensing surface 234, the two third sensors 232b are used to measure the first spatial coordinates of the transfer stamp 220 at the first position and the second spatial coordinates of the transfer stamp 220 at the second position.

In an embodiment, two first sensors 231a are used to sense and measure the first spatial coordinates of the first position corresponding to the first sensing surface 233 and the second spatial coordinates of the second position. This allows the present application to obtain the displacement result of the transfer stamp 220 relative to the Y direction and the rotation angle result around the X axis during the lifting movement. The second sensor 232a and the third sensor 232b located above are used to sense and measure the first spatial coordinates and the second spatial coordinates of the first position corresponding to the second sensing surface 234 and the third sensing surface 235. This allows the present application to obtain the rotation angle result of the transfer stamp 220 around the Z axis during the lifting movement. In addition, two third sensors 232b are used to measure the first spatial coordinates of the first position corresponding to the third sensing surface 235 and the second spatial coordinates of the second position. This allows the present application to obtain the displacement result of the transfer stamp 220 relative to the X direction and the rotation angle result around the Y axis during the lifting movement. Finally, the present application can measure the displacement or deflection value of the transfer stamp 220 relative to any position during specific implementation, thereby solving the technical defect that the related art cannot accurately control the alignment accuracy between the transfer stamp 220 and the semiconductor components since the motion error of the transfer stamp 220 during the lifting process cannot be measured.

It should be noted that, in an embodiment, in order to avoid the defect that the transfer stamp 220 cannot accurately measure the error value due to rotation around one of the points during the lifting movement, it is necessary to ensure that at least two sensors spaced apart along the Z direction are respectively provided at the plate surface of the first vertical plate 241 extending along the X direction and located in the transfer space, and the plate surface of the second vertical plate 242 extending along the Y direction and located in the transfer space. It is also necessary to ensure that at least two sensors spaced apart along the Y direction are provided at the plate surface of the second vertical plate 242 located in the transfer space. In this way, it is also avoided that the transfer stamp 220 cannot measure the deflection or offset value due to rotation around one of the points during the specific implementation. At the same time, in order to improve the guiding accuracy, at least two first guide rails 250 extending along the Z direction are provided and spaced apart. At the same time, the transfer stamp 220 can perform lifting movement along the Z direction relative to the two first guide rails 250.

In an embodiment, in order to further improve the load capacity, a second guide rail 270 extending along the Z direction is further provided at the first vertical plate 241. A second slider 280 slidably matched with the second guide rail 270 is further provided at the transfer stamp 220. The second guide rail 270 and the lifting drive member 210 are provided at intervals.

In an embodiment, a second guide rail 270 extending along the Z direction is provided at the first vertical plate 241, so that the transfer stamp 220 can slide with the first slide rail through the second slider 280, and when the present application is implemented, it can ensure that the transfer stamp 220 moves more smoothly when lifting and falling along the Z direction.

In an embodiment, a first horizontal drive member is further provided at the support frame 120. The mounting plate 240 is connected to the first horizontal drive member. The first horizontal drive member can drive the mounting plate 240 to move along the Y direction, thereby driving the transfer mechanism 200 to move along the Y direction.

In an embodiment, a first horizontal drive member is provided at the support frame 120, and the mounting plate 240 is connected to the first horizontal drive member. The mounting plate 240 is driven to move along the Y direction by the first horizontal drive member, so as to drive the transfer mechanism 200 to move along the Y direction. In the specific implementation of the present application, the alignment accuracy of the transfer stamp 220 with the first placement area 310 or the second placement area 320 can be changed by driving the mounting plate 240 to move. In addition, the present application can ensure that the transfer stamp 220 is aligned with the first placement area 310 or the second placement area 320 in the specific implementation.

In an embodiment, an alignment space can be formed between the material transport mechanism 300 and the transfer stamp 220. A first alignment point is provided at the bottom surface of the transfer stamp 220. A second alignment point is provided at the first placement area 310 or the second placement area 320.

The support frame 120 is also provided with an alignment mechanism 400. The alignment mechanism 400 includes a second horizontal drive member 410 and an alignment component 420. The first horizontal drive member and the second horizontal drive member 410 are provided at intervals. The second horizontal drive member 410 is installed at the gantry support frame 120. The alignment component 420 is connected to the second horizontal drive member 410. The second horizontal drive member 410 can drive the alignment component 420 to enter the alignment space along the Y direction, and is used to sense the first alignment point and the second alignment point.

In an embodiment, a first alignment point is provided at the bottom surface of the transfer stamp 220, a second alignment point is provided at the first placement area 310 or the second placement area 320, and the alignment component 420 is used to sense the first alignment point and the second alignment point. This allows the present application to accurately measure the alignment effects of the first alignment point and the second alignment point during specific implementation.

It is necessary to specifically and clearly explain that the second alignment point in the embodiment of the present is an alignment point on the first placement area 310 or the second placement area 320 directly opposite to the transfer stamp 220. It is clearly understood that when the first placement area 310 is directly opposite to the transfer stamp 220, the second alignment point is an alignment point on the first placement area 310; when the second placement area 320 is directly opposite to the transfer stamp 220, the second alignment point is an alignment point on the second placement area 320.

In an embodiment, the alignment component 420 includes a mounting seat 421, a first collector 422, and a second collector 423. The mounting seat 421 is connected to the output end of the second horizontal drive member 410. The first collector 422 and the second collector 423 are coaxially mounted on the mounting seat 421 along the Z direction. The first collector 422 corresponds to the transfer stamp 220 and is used to sense the first alignment point. The second collector 423 corresponds to the first placement area 310 or the second placement area 320 and is used to sense the second alignment point.

In an embodiment, the first collector 422 is coaxially provided to sense and obtain the first alignment point of the transfer stamp 220. The second collector 423 senses and obtains the second alignment point of the first placement area 310 or the second placement area 320. This allows the present application to accurately determine the alignment effect between the transfer stamp 220 and the first placement area 310 or the second placement area 320 during specific implementation.

Based on the same technical concept, as shown in FIG. 8, in the second aspect, the present application provides a method for transferring the semiconductor component, applied with the device for transferring the semiconductor component in the first aspect.

The method includes the following steps.
S100, obtaining the first spatial coordinates of the transfer stamp at the first position, where the first placement area is directly below the transfer stamp.

In an embodiment, it is necessary to use the two first sensors 231a, the second sensor 232a and the two third sensors 232b that have been installed to simultaneously obtain the first spatial coordinates corresponding to the transfer stamp 220 when it is in the first position. It can be clearly stated that the first spatial coordinates obtained include the spatial coordinates of the corresponding positions sensed and measured by the two first sensors 231a, the second sensor 232a and the two third sensors 232b respectively. That is, when the present application is implemented, it is necessary to use the two first sensors 231a, the second sensor 232a and the two third sensors 232b to simultaneously measure the five spatial coordinates of the transfer stamp 220 when it is located at the first position.
S200, moving the transfer stamp from the first position to the second position, obtaining the second spatial coordinates of the transfer stamp at the second position.

In an embodiment, five second spatial coordinates are also provided as the first spatial coordinates.
S300, calculating a posture error of the transfer stamp after movement according to the first spatial coordinates and the second spatial coordinates.
S400, correcting the transfer stamp according to the posture error.
S500, adsorbing the semiconductor component placed on the first placement area.
S600, in response that the second placement area being opposite to the transfer stamp, placing the semiconductor component in the second placement area. The motion mechanism moves to make the second placement area 320 opposite to the bottom of the transfer stamp 220, and the semiconductor components adsorbed on the transfer stamp 220 are placed in the second placement area 320 accordingly.

In an embodiment, the step of calculating the posture error of the transfer stamp after movement according to the first spatial coordinates and the second spatial coordinates includes:
calculating first error data of the transfer stamp using formula 1 according to the first spatial coordinate and the second spatial coordinates; the first error data includes the displacement error ΔX of the transfer stamp along the X direction and the displacement error ΔY along the Y direction, and the formula 1 is:

$$\{ \begin{matrix}Δ X = \frac{{X}_{Ai} + {X}_{Ci}}{2} \\ Δ Y = \frac{{Y}_{Di} + {Y}_{Ei}}{2}\end{matrix} .$$

X_{Ai} is an X axis coordinate change of a third sensor 232b located above, X_{Ci} is an X axis coordinate change of a third sensor 232b located below, Y_{Di} is a Y axis coordinate change of a first sensor located above, and Y_{Ei} is a Y axis coordinate change of a first sensor 231a located below.
Calculating a rotation angle error Rₓ of the transfer stamp around the X axis, a rotation angle error R_{y} of the transfer stamp around the Y axis, and a rotation angle error R_{z} of the transfer stamp around the Z axis using formula 2, and the formula 2 is:

$$\{ \begin{matrix}{R}_{x} = a tan ( \frac{{Y}_{Di} - {Y}_{Ei}}{{L}_{3}} ) \\ {R}_{y} = a tan ( \frac{{X}_{Ai} - {X}_{Ci}}{{L}_{2}} ) \\ {R}_{z} = a tan ( \frac{{X}_{Ai} - {X}_{Bi}}{{L}_{1}} )\end{matrix}$$

X_{Bi} is an X axis coordinate change of the second sensor 232a, L₁ is a horizontal distance between the second sensor 232a and the third sensor 232b located above, L₂ is a vertical height of the two third sensors 232b along the Z axis, and L₃ is a vertical height of the two first sensors 231a along the Z axis.
Calculating a displacement result of the transfer stamp using formula 3 according to the movement stroke Hz of the transfer stamp, ΔX, ΔY, Rₓ and R_{y} to obtain the posture error of the transfer stamp after movement. The displacement result includes the displacement value in the X direction and the displacement value in the Y direction, and formula 3 is:

$$\{ \begin{matrix}{X}_{1} = Δ X - ( {H}_{z} + \frac{{L}_{3}}{2} + {δ}_{x} ) tan {R}_{y} \\ {Y}_{1} = Δ Y - ( {H}_{z} + \frac{{L}_{2}}{2} + {δ}_{y} ) tan {R}_{x}\end{matrix} ,$$

δₓ is a vertical distance between the bottom surface of the transfer stamp 220 and the third sensor 232b located below, and δ_{y} is a vertical distance between the bottom surface of the transfer stamp 220 and the first sensor 231a located below.

In an embodiment, the device of the present application can also be implemented as follows.

Compared with other existing display technologies, such as LCD and OLED, Micro LED display technology has the advantages of high contrast, high brightness, low power consumption, long life, ultra-thin flexible display, etc., and is regarded as a disruptive and revolutionary next-generation display technology. At present, the manufacturing technology of Micro LED display is to use mass transfer technology to transfer the prepared Micro LED chip to the drive circuit backplane. Specifically, the Micro LED chip manufacturer first manufactures or places the required Micro LED chip on a temporary carrier, and the customer then transfers the Micro LED chip placed on the temporary carrier to the drive circuit of different products according to different needs. However, the size of Micro LED is very small, from tens of microns to several microns. In the process of transferring the Micro LED chip from the temporary carrier to the drive circuit backplane, extremely high transfer accuracy is required, generally about 5% of the size of Micro LED. When the transfer stamp 220 picks up the Micro LED chip on the temporary carrier or releases the Micro LED chip to the drive circuit backplane, it is necessary to first align the transfer stamp 220 with the Micro LED chip on the temporary carrier or the drive circuit backplane, and the alignment action is completed by the alignment unit. During alignment, the alignment unit is located between the transfer stamp 220 and the temporary carrier or the drive circuit backplane. After the alignment is completed, the alignment unit moves horizontally. Limited by the size of the alignment unit, after the transfer stamp 220 and the target are aligned, a large stroke (such as more than 200 mm) downward movement is required to complete the high-precision pickup or release of the Micro LED chip. In addition, it is difficult for the existing guide rail to ensure sub-micron motion accuracy under a large stroke, so that after the transfer stamp 220 is aligned with the temporary carrier or the drive circuit backplane, relying solely on the large stroke up and down movement of the guide rail cannot guarantee the accurate pickup of the Micro LED chip or the accurate placement of the Micro LED chip in the predetermined position on the drive circuit backplane, resulting in a decrease in the transfer yield and affecting subsequent related processes. At present, laser interferometers, photoelectric autocollimators and other instruments can only measure a single parameter or two degrees of freedom errors at a time for the motion error of the guide rail, which are an offline measurement and it is difficult to achieve online measurement, making it time-consuming and labor-intensive.

The technical problem to be solved by the present application: providing a device and a method for transferring the semiconductor component to solve the problem that after the transfer stamp 220 in the lifting motion unit is aligned with the target unit, i.e., the temporary carrier or the drive circuit backplane, the transfer stamp 220 in the lifting motion unit cannot accurately move to the predetermined position of the target unit due to the large motion error of the guide rail under the large stroke lifting motion, resulting in the transfer stamp 220 being unable to smoothly pick up or release the Micro LED chip, thereby reducing the transfer yield and affecting the subsequent related processes.

The present application provides a device for transferring the semiconductor component. The position and posture of a lifting workbench can be detected online. The requirements of the lifting workbench on the motion accuracy of the guide rail are reduced. A control method is provided to perform submicron-level precise picking or releasing operations on Micro LED chips under large-stroke lifting motion, thereby improving the qualified rate of mass transfer.

The present application aims to solve the problem that the transfer stamp 220 cannot accurately pick up or release the chip due to the motion error of the lifting guide rail during the mass transfer of chips. An upgraded motion device and method for mass transfer of chips are provided. The lifting workbench can be measured online and feedback controlled to achieve sub-micron high-precision lifting motion control, thereby improving the yield of chip transfer.

The present application provides a device and a method for transferring the semiconductor component. Through online measurement feedback control, submicron lifting and falling motion control of the transfer stamp 220 is realized. It is ensured that the transfer stamp 220 can accurately pick up the Micro LED chip on the temporary carrier or accurately release the Micro LED chip to the drive circuit backplane. As shown in FIG. 1, the device includes a base frame 100, a material transport mechanism 300, a support frame 120, a transfer mechanism 200 and an alignment mechanism 400. A first placement area 310 and a second placement area 320 are fixedly placed on the material transport mechanism 300. In an embodiment, the material transport mechanism 300 can move along the X direction. The first placement area 310 and the second placement area 320 can be moved to the bottom of the transfer mechanism 200 to complete the picking or releasing operation. The first placement area 310 and the second placement area 320 are used to carry the chip temporary carrier and the drive circuit backplane respectively. In an embodiment, a driving mechanism is provided to rotate around the X, Y and Z axes respectively to adjust the posture. The transfer mechanism 200 is installed at the support frame 120. In an embodiment, a driving mechanism may be provided to enable the transfer mechanism 200 to move along the Y axis. The description of the movement mode of the material transport mechanism 300, the support frame 120, and the first placement area 310 and the second placement area 320 is only for better explanation of the specific embodiment. However, the movement mode is not unique, other movement combinations may also be used to complete the corresponding movement control.

The transfer mechanism 200 includes a lifting workbench, a mounting plate 240, a lifting drive member 210, a guide rail, and a spectral confocal sensor.

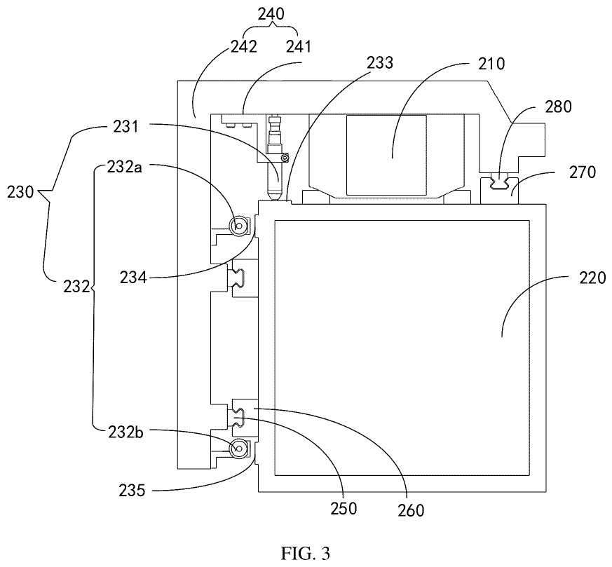

A transfer stamp 220 is carried at the bottom of the lifting workbench. The transfer stamp 220 can be a transfer stamp 220 made by van der Waals force, electrostatic force or magnetic force, which is used to complete the chip picking or releasing operation. As shown in FIG. 3, three reference surfaces are further provided at the side of the lifting workbench. The third sensing surface 235 and the second sensing surface 234 are located at the same plane and parallel to the YZ plane, and the first sensing surface 233 is parallel to the XZ plane. The reference surface is used as a reference plane with high surface accuracy is very high, and the surface morphology error thereof is negligible compared to the accuracy of the sensor.

Three linear guide rails are installed in parallel along the vertical Z direction on the mounting plate 240. They are the first guide rail 250 and the second guide rail 270 used to guide and fix the lifting workbench. A lifting drive member 210 is also installed in the vertical direction on the mounting plate 240 to drive the lifting workbench to move up and down along the Z direction. A built-in grating ruler is used to measure the movement value of the lifting workbench along the Z direction.

The first sensor 231a, the second sensor 232a and the third sensor 232b are installed at the mounting plate 240. The above sensors may be the ranging sensor configured to measure distance. The third sensor 232b located above and the second sensor 232a are installed horizontally along the Y direction in the YZ plane. The connecting line between the third sensor 232b located above and the second sensor 232a is perpendicular to the motion direction of the guide rail. The third sensor 232b located above and the second sensor 232a are cooperated with the third sensing surface 235 and the second sensing surface 234 to form a rotation angle measurement unit around Z. The third sensor 232b located above and the third sensor 232b located below are installed vertically along the Z direction in the YZ plane. The connecting line between the third sensor 232b located above and the third sensor 232b located below is parallel to the motion direction of the guide rail. The third sensor 232b located above and the third sensor 232b located below are cooperated with the third sensing surface 235 to form a rotation angle measurement unit around Y axis and a displacement measurement unit along X direction. The first sensor 231a located above and the first sensor 231a located below are installed vertically in the Z direction. The first sensor 231a located above and the first sensor 231a located below are cooperated with the first sensing surface 233 to form a rotation angle measurement unit around X axis and a displacement measurement unit along Y direction. The distance measuring sensor may adopt a spectral confocal sensor, an eddy current sensor, and a capacitive sensor, etc. In an embodiment, the spectral confocal sensor is adopted and installed at the mounting plate 240, with the advantage that the interference of the spectral confocal sensor cable on the lifting movement of the lifting workbench can be avoided.

The alignment mechanism 400 is used to align the transfer stamp 220 carried on the upgrade workbench with the first placement area 310 or the second placement area 320. During the alignment process, the alignment mechanism 400 is located between the transfer stamp 220 and the placement area. After the alignment is completed, the alignment mechanism 400 moves horizontally. Limited by the size of the alignment mechanism 400, the transfer stamp 220 needs to perform a large-stroke lifting movement after the alignment is completed to complete the chip picking or releasing operation.

The present application also provides a method for transferring the semiconductor component, including the following steps:
mounting a lifting motion unit;
determining the initial position state;
obtaining the change relative to the starting measurement point;
calculating the posture error after movement; and
maintaining the transfer stamp 220 in the lifting workbench and the first water table 5 to be in the initial alignment state in the determining the initial position state after the movement according to the measurement results ΔX, ΔY, Rx, Ry and Rz, and the movement stroke Hz of the lifting workbench.

Two first sensors 231a, one second sensor 232a and two third sensors 232b are mounted at the mounting plate 240, and are adjusted to ensure that the horizontal distance between the two probes of the second sensor 232a and the third sensor 232b located above is L₁. The second sensor 232a is perpendicular to the third sensing surface 235 and the second sensing surface 234. The connecting line between the two probes is perpendicular to the movement direction of the guide rail. The vertical distance between the two third sensors 232b along the Z direction is L₂. The connecting line between the two third sensors 232b is parallel to the movement direction of the first guide rail 250. The vertical distance between the two probes of the two first sensors 231a along the Z direction is L₃. The two first sensors 231a are perpendicular to the first sensing surface 233 and the connecting line between the two probes is parallel to the movement direction of the second guide rail 270. According to the appliance for mass transfer of chips of the present application, in an embodiment, the measurement accuracy of the spectral confocal sensor can be ±150 nm or higher. The distance L₁ is 200 mm, distance L₂ is 300 mm, and distance L₃ is 300 mm. The movement range of the lifting workbench Hz is 300 mm.

The transfer stamp 220 and the first placement area 310 in the lifting workbench are aligned in a predetermined manner through the alignment mechanism 400. At this time, the alignment mechanism 400 moves between the lifting workbench and the first placement area 310. The alignment is completed by the alignment mechanism 400. The transfer stamp 220 and the first placement area 310 in the lifting workbench are aligned in the horizontal direction and the planes where the two are located are parallel. At this time, there is no position deviation between the transfer stamp 220 and the first placement area 310 in the lifting workbench long the horizontal direction. After the alignment is completed, the alignment mechanism 400 is moved out horizontally. The reading obtained by the spectral confocal sensor at this time is used as the starting measurement point and a reference benchmark.

The lifting workbench moves downward along the guide rail by Hz under the drive of the lifting drive member 210. The five spectral confocal sensors scan their corresponding reference surfaces respectively. When moving to the current position, the change of each spectral confocal sensor relative to the starting measurement point is X_{Ai}, X_{Bi}, X_{Ci}, Y_{Di} and Y_{Ei} respectively. After the movement, if each sensing surface is away from the spectral confocal sensor, the change is positive, and if each sensing surface is not away from the spectral confocal sensor, the change is negative.

According to the installation position and reading of each spectral confocal sensor, the lateral displacement error along the X direction and the lateral displacement error along the Y direction generated by the lifting workbench relative to the starting point after the lifting movement are calculated by the formula (1):

$$\{ \begin{matrix}Δ X = \frac{{X}_{Ai} + {X}_{Ci}}{2} \\ Δ Y = \frac{{Y}_{Di} + {Y}_{Ei}}{2}\end{matrix} \qquad ( 1 )$$

The rotation angle error around the X axis is Rx, the rotation angle error around the Y axis is Ry and the rotation angle error around the Z axis is Rz, which can be calculated using formula (2):

$$\{ \begin{matrix}{R}_{x} = a tan ( \frac{{Y}_{Di} - {Y}_{Ei}}{{L}_{3}} ) \\ {R}_{y} = a tan ( \frac{{X}_{Ai} - {X}_{Ci}}{{L}_{2}} ) \\ {R}_{z} = a tan ( \frac{{X}_{Ai} - {X}_{Bi}}{{L}_{1}} )\end{matrix} \qquad ( 2 )$$

The lateral displacement value X₁ of the transfer stamp 220 in the lifting workbench relative to the first placement area 310 in the horizontal direction along the X direction and the lateral displacement value Y₁ along the Y direction are obtained by formula (3).

$$\{ \begin{matrix}{X}_{1} = Δ X - ( {H}_{z} + \frac{{L}_{3}}{2} + {δ}_{x} ) tan {R}_{y} \\ {Y}_{1} = Δ Y - ( {H}_{z} + \frac{{L}_{2}}{2} + {δ}_{y} ) tan {R}_{x}\end{matrix} \qquad ( 3 )$$

In the above formula, δₓ is the vertical distance from the transfer stamp 220 to the measuring point corresponding to the third sensor 232b located below, and δ_{y} is the vertical distance from the transfer stamp 220 to the measuring point corresponding to the first sensor 231a located below after the alignment in the determining the initial position state is completed. The distance value is small and can be ignored to a certain extent.

Feedback controls the movement of the support frame 120 and the material transport mechanism 300, so that the transfer stamp 220 in the lifting workbench and the horizontal workbench on the material transport mechanism 300 are kept in a horizontal alignment state, thereby achieving the operation of accurately picking up or releasing the chip. According to the parameters of the mounting the lifting motion unit, the measurement accuracy of X₁ and Y₁ can reach the sub-micron level.

The present application provides a base frame 100. A support frame 120 is installed at the transport platform 110 of the base frame 100. The lifting drive member 210 and the sensing component 230 in the transfer mechanism 200 are installed at intervals on the support frame 120. The transfer stamp 220 is installed at the lifting drive member 210 and is located above the transport platform 110. The lifting drive member 210 can drive the transfer stamp 220 to rise and fall along the Z direction between the first position and the second position. The sensing component 230 is provided close to the lifting path of the transfer stamp 220. The sensing component 230 is used to sense the first spatial coordinates of the transfer stamp 220 at the first position and the second spatial coordinates at the second position. At the same time, the material transport mechanism 300 is installed at the transport platform 110 and penetrated in the support frame 120. The material transport mechanism 300 is provided below the sensing component 230. The material transport mechanism 300 is provided with a first placement area 310 and a second placement area 320 configured to place the semiconductor components. The material transport mechanism 300 can move along the X direction so that the first placement area 310 or the second placement area 320 corresponds to the transfer stamp 220. Then, when the first placement area 310 corresponds to the transfer stamp 220, the transfer stamp 220 can adsorb the semiconductor components placed in the first placement area 310. When the second placement area 320 corresponds to the transfer stamp 220, the transfer stamp 220 can place the adsorbed semiconductor components in the second placement area 320. The purpose of accurately measuring the movement accuracy of the transfer stamp 220 when using the transfer stamp 220 to transfer semiconductor components, which can improve the alignment accuracy between the transfer stamp 220 and the semiconductor components, ensure the yield rate of the prepared products, and solve the problem in the related art that after the transfer stamp 220 is aligned with the temporary carrier or the drive circuit backplane, it can't be ensured that the Micro LED chip is accurately picked up or placed in the predetermined position of the driver circuit backplane relying solely on the large stroke up and down movement of the guide rail, resulting in a decrease in the transfer yield and affecting subsequent related processes.

The above are only some embodiments of the present application, and do not limit the scope of the present application thereto. Under the inventive concept of the present application, equivalent structural transformations made according to the description and drawings of the present application, or direct/indirect application in other related technical fields are included in the scope of the present application.

What is claimed is:

1. A device for transferring a semiconductor component, comprising:
a base frame comprising a transport platform and a support frame installed at the transport platform;
a transfer mechanism comprising a lifting drive member, a transfer stamp and a sensing component; and
a material transport mechanism installed at the transport platform and penetrating the support frame;
wherein the lifting drive member and the sensing component are installed at intervals at the support frame, the transfer stamp is installed at the lifting drive and is located above the transport platform, the lifting drive is configured to drive the transfer stamp to rise and fall along a Z direction between a first position and a second position, the sensing component is provided close to a lifting path of the transfer stamp, and the sensing component is configured to sense first spatial coordinates of the transfer stamp at the first position and second spatial coordinates of the transfer stamp at the second position;
the material transport mechanism is provided below the sensing component, the material transport mechanism is provided with a first placement area and a second placement area for placing the semiconductor component, and the material transport mechanism is configured to move along an X direction to correspond the first placement area or the second placement area with the transfer stamp; and
in response to that the first placement area correspond to the transfer stamp, the transfer stamp is configured to adsorb the semiconductor component placed in the first placement area; and in response to that the second placement area correspond to the transfer stamp, the transfer stamp is configured to place the adsorbed semiconductor component in the second placement area.

2. The device according to claim 1, wherein a mounting plate is provided at the support frame, the mounting plate comprises a first vertical plate provided along the X direction and a second vertical plate provided along a Y direction, one side of the first vertical plate is connected to one side of the second vertical plate, the first vertical plate and the second vertical plate are enclosed to form a lifting space, the transfer stamp is located in the lifting space, the lifting drive member is installed at a side of the first vertical plate facing the lifting space, a side of the second vertical plate facing the lifting space is provided with a first guide rail extending along the Z direction, the transfer stamp is provided with a first slider slidably matched with the first guide rail, and the sensing component is installed at a side wall of the lifting space.

3. The device according to claim 2, wherein the sensing component comprises a first sensing component installed at the first vertical plate and a second sensing component installed at the second vertical plate, a first sensing area extending along the Z direction is formed on a side of the transfer stamp corresponding to the first vertical plate, and a second sensing area extending along the Z direction is formed on a side of the transfer stamp corresponding to the second vertical plate; the first sensing component is configured to sense the first spatial coordinates and the second spatial coordinates of the first sensing area, and the second sensing component is configured to sense the first spatial coordinates and the second spatial coordinates of the second sensing area.

4. The device according to claim 3, wherein the first sensing region is formed with a first sensing surface extending along the Z direction, the second sensing region is formed with a second sensing surface extending along the Z direction and a third sensing surface extending along the Z direction and spaced apart from the second sensing surface;
the first sensing component comprises two first sensors provided at intervals along the Z direction, and the two first sensors correspond to the first sensing surface, the second sensing component comprises a second sensor and two third sensors provided at intervals along the Z direction, the second sensor is provided opposite to the second sensing surface, the two third sensors are opposite to the third sensing surface, the second sensor and the two third sensors are provided at intervals along the Y direction, and the second sensor, the two first sensors and the two third sensors are all configured to sense the first spatial coordinates and the second spatial coordinates.

5. The device according to claim 2, wherein the first vertical plate is further provided with a second guide rail extending along the Z direction, the transfer stamp is further provided with a second slider slidably matched with the second guide rail, and the second guide rail is provided at intervals from the lifting drive member.

6. The device according to claim 2, wherein the support frame is further provided with a first horizontal drive member, the mounting plate is connected to the first horizontal drive member, and the first horizontal drive member is configured to drive the mounting plate to move along the Y direction to drive the transfer mechanism to move along the Y direction.

7. The device according to claim 6, wherein an alignment space is formed between the material transport mechanism and the transfer stamp, a first alignment point is provided at a bottom surface of the transfer stamp, and a second alignment point is provided at both the first placement area and the second placement area;
an alignment mechanism is installed at the support frame, the alignment mechanism comprises a second horizontal drive member and an alignment component, the first horizontal drive member and the second horizontal drive member are provided at an interval, and the second horizontal drive member is installed at the support frame, the alignment component is connected to the second horizontal drive member, the second horizontal drive member is configured to drive the alignment component to enter the alignment space along the Y direction, and sense the first alignment point and the second alignment point.

8. The device according to claim 7, wherein the alignment component comprises a mounting seat, a first collector and a second collector, the mounting seat is connected to the output end of the second horizontal drive member, the first collector and the second collector are coaxially mounted on the mounting seat along the Z direction, the first collector corresponds to the transfer stamp and is used to sense the first alignment point, and the second collector corresponds to the first placement area or the second placement area and is configured to sense the second alignment point.

9. A method for transferring a semiconductor component, applied to the device for transferring the semiconductor component according to claim 1, comprising:
obtaining the first spatial coordinates of the transfer stamp at the first position, wherein the first placement area is directly below the transfer stamp;
obtaining the second spatial coordinates of the transfer stamp at the second position;
calculating a posture error of the transfer stamp after movement according to the first spatial coordinates and the second spatial coordinates;
correcting the transfer stamp according to the posture error;
adsorbing the semiconductor component placed on the first placement area; and
in response that the second placement area being opposite to the transfer stamp, placing the semiconductor component in the second placement area.

10. The method according to claim 9, wherein the calculating the posture error of the transfer stamp after movement according to the first spatial coordinates and the second spatial coordinates comprises:
calculating first error data of the transfer stamp using formula 1 according to the first spatial coordinates and the second spatial coordinates; wherein the first error data ΔX comprises the displacement error of the transfer stamp along the X direction and the displacement error ΔY along the Y direction, and the formula 1 is:
$$\{ \begin{matrix}Δ X = \frac{{X}_{Ai} + {X}_{Ci}}{2} \\ Δ Y = \frac{{Y}_{Di} + {Y}_{Ei}}{2}\end{matrix} ,$$
wherein X_{Ai} is an X axis coordinate change of a third sensor located above, X_{Ci} is an X axis coordinate change of a third sensor located below, Y_{Di} is a Y axis coordinate change of a first sensor located above, and Y_{Ei} is a Y axis coordinate change of a first sensor located below;
calculating a rotation angle error Rₓ of the transfer stamp around the X axis, a rotation angle error R_{y} of the transfer stamp around the Y axis, and a rotation angle error R_{z} of the transfer stamp around the Z axis using formula 2, wherein formula 2 is:
$$\{ \begin{matrix}{R}_{x} = a tan ( \frac{{Y}_{Di} - {Y}_{Ei}}{{L}_{3}} ) \\ {R}_{y} = a tan ( \frac{{X}_{Ai} - {X}_{Ci}}{{L}_{2}} ) \\ {R}_{z} = a tan ( \frac{{X}_{Ai} - {X}_{Bi}}{{L}_{1}} )\end{matrix} ,$$
wherein X_{Bi} is an X axis coordinate change of the second sensor, L₁ is a horizontal distance between the second sensor and the third sensor located above, L₂ is a vertical height of the two third sensors along the Z axis, and L₃ is a vertical height of the two first sensors along the Z axis;
calculating a displacement result of the transfer stamp using formula 3 according to the movement stroke Hz of the transfer stamp, ΔX, ΔY, Rₓ and R_{y} to obtain the posture error of the transfer stamp after movement; wherein the displacement result comprises the displacement value X₁ in the X direction and the displacement value Y₁ in the Y direction, and formula 3 is:
$$\{ \begin{matrix}{X}_{1} = Δ X - ( {H}_{z} + \frac{{L}_{3}}{2} + {δ}_{x} ) tan {R}_{y} \\ {Y}_{1} = Δ Y - ( {H}_{z} + \frac{{L}_{2}}{2} + {δ}_{y} ) tan {R}_{x}\end{matrix} ;$$
wherein δₓ is a vertical distance between the bottom surface of the transfer stamp and the third sensor located below, and δ_{y} is a vertical distance between the bottom surface of the transfer stamp and the first sensor located below.
